(19) United States
(12) Patent Application Publication
(10) Pub. No.: US 2026/0076269 A1
(43) Pub. Date: Mar. 12, 2026

(54) SEMICONDUCTOR DEVICE AND OPERATING METHOD THEREOF

(71) Applicant: TAIWAN SEMICONDUCTOR MANUFACTURING COMPANY LTD., HSINCHU (TW)

(72) Inventor: YU-HSUN LI, YUNLIN COUNTY (TW)

(21) Appl. No.: 18/826,253

(22) Filed: Sep. 6, 2024

(51) Int. Cl. H01L 23/498; B81B 3/00; B81C 1/00; H01L 23/00; H01L 23/473; H01L 25/065; H01L 25/18

(52) U.S. Cl. CPC H10W 90/701; B81B 3/0021; B81C 1/0015; H10W 40/47; H10W 70/635; H10W 90/00; B81B 2201/0278; B81B 2203/0136; B81B 2207/015; B81C 2203/032; B81C 2203/0714; H10W 90/722; H10W 90/724

(57) ABSTRACT

The present disclosure provides a semiconductor device. The semiconductor device includes: a circuit board; a packaging structure disposed over and bonded to the circuit board; and a MEMS structure disposed over and bonded to the packaging structure and including a movable element. The movable element is movable relative to the packaging structure and the circuit board upon an operation of the packaging structure.

### BACKGROUND

The semiconductor integrated circuit (IC) industry has experienced exponential growth. Technological advances in IC materials and design have produced generations of ICs where each generation has smaller and more complex circuits than the previous generation.

As technological standards advance, there is an ever-increasing consumer demand for semiconductor ICs that occupy less space, consume less power, and perform higher-quality computing at greater speeds. As a result, there remains a need to develop methods for manufacturing and operating improved semiconductor devices.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic cross-sectional view of a semiconductor device according to some embodiments of the present disclosure.

FIG. 2 is a schematic cross-sectional view of a MEMS structure of the semiconductor device in FIG. 1 according to some embodiments of the present disclosure.

FIG. 3A is a schematic cross-sectional view of another semiconductor device according to various embodiments of the present disclosure.

FIG. 3B is a schematic cross-sectional view of another semiconductor device according to various embodiments of the present disclosure.

FIG. 4 is a flow diagram showing a method for manufacturing the MEMS structure in FIG. 2 according to some embodiments of the present disclosure.

FIGS. 5 to 25 are schematic cross-sectional views illustrating sequential operations of the method in FIG. 4 according to some embodiments of the present disclosure.

FIG. 26 is a flow diagram showing a method for operating the semiconductor device in FIG. 1 according to some embodiments of the present disclosure.

FIG. 27 is a schematic perspective view illustrating an implementation of the method in FIG. 26 according to some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In some embodiments, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element or feature as illustrated in the figures. The spatially relative terms are intended to encompass orientations of the device in use or operation in some embodiments different from the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range which can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of time, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A complementary metal-oxide semiconductor (CMOS) process is one of many commercial semiconductor processes that are used to produce integrated circuits (ICs). The use of the CMOS processes to develop microelectromechanical system (MEMS) devices is called CMOS-MEMS technology. Many sensors and devices are fabricated and commercialized using such technology; examples include accelerometers, pressure sensors, thermal sensors, image sensors, microphones, inkjet heads, and digital micro-mirror devices. Micro-scale devices developed using CMOS-MEMS technology have potential for successful commercialization and mass production.

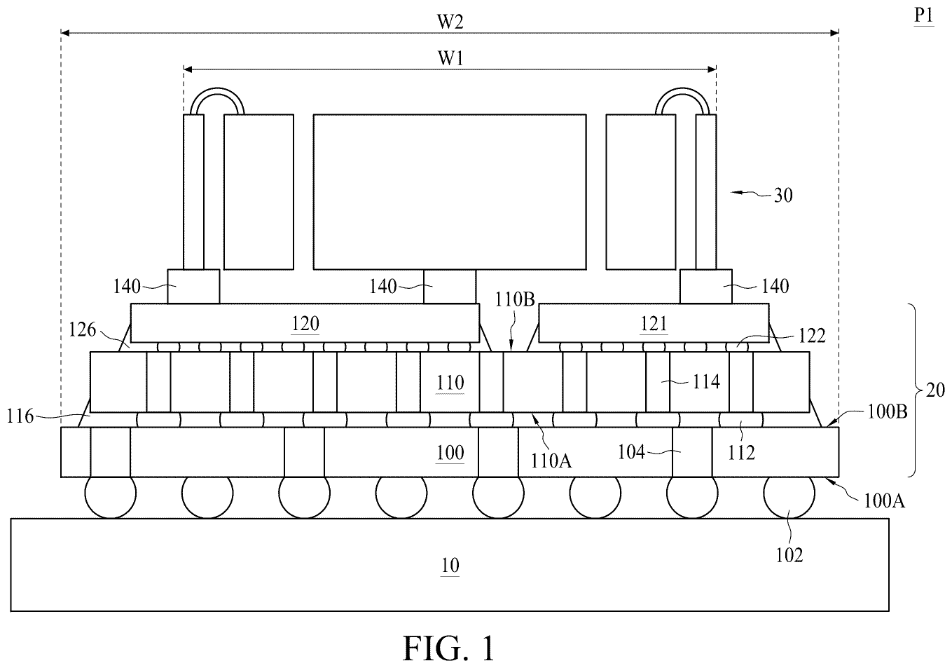

FIG. 1 is a schematic cross-sectional view of a semiconductor device P1 according to some embodiments of the present disclosure. In some embodiments, the semiconductor device P1 includes a circuit board 10, a packaging structure 20 disposed over the circuit board 10, and a MEMS structure or an actuating structure 30 disposed over the packaging structure 20. The circuit board 10 may be a printed circuit board (PCB) formed of polypropylene (PP) and may be a single-layer or a multilayer structure.

The packaging structure 20 is bonded to the circuit board 10 via multiple conductive connectors 102 by, for example, surface mounting. The conductive connectors 102 may be formed of metals such as copper (Cu), aluminum (Al), gold (Au), nickel (Ni), silver (Ag), platinum (Pt), tin (Sn), or a combination thereof. The conductive connectors 102 may have various configurations. For example, the conductive connectors 102 are solder balls, bumps, pads or pillars. The conductive connectors 102 allow an electrical connection between the packaging structure 20 and the circuit board 10.

In some embodiments, the packaging structure 20 includes a package substrate 100, an interposer 110 disposed over the package substrate 100, and a semiconductor chip 120 disposed over the interposer 110. In some embodiments, another semiconductor chip 121 is also disposed over the interposer 110.

The package substrate 100 has a first surface 100A facing to the circuit board 10 and a second surface 100B opposite to the first surface 100A. The package substrate 100 may be made of bismaleimide triazine (BT) resin, ceramic, glass, plastic, tape, film, or other supporting materials that may carry conductive materials needed to receive and transmit electrical signals. The package substrate 100 may be a single-layer circuit board or a multiple-layer circuit board. In some embodiments, the package substrate 100 includes redistribution lines and/or conductive vias 104 for providing electrical connections.

The interposer 110 is bonded to the second surface 100B of the package substrate 100 via multiple conductive connectors 112 by, for example, surface mounting. The conductive connectors 112 may be formed of metals such as copper, aluminum, gold, nickel, silver, platinum, tin, or a combination thereof. The conductive connectors 112 may have various configurations. For example, the conductive connectors 112 are solder balls, bumps, pads or pillars. In some embodiments, the conductive connectors 112 are controlled collapsed chip connection (C4) bumps. The conductive connectors 112 allow an electrical connection between the interposer 110 and the package substrate 100. In some embodiments, the redistribution lines and/or conductive vias 104 are electrically connected to the conductive connectors 102 and 112.

In the embodiments, the interposer 110 is bonded to the package substrate 100 after the semiconductor chips 120 and 121 are mounted on the interposer 110. In some embodiments, the interposer 110 is a silicon (Si) interposer. Redistribution lines and/or conductive vias 114 may be formed in the interposer 110 to electrically couple conductive pads (not shown) disposed on opposite surfaces 110A and 110B of the interposer 110.

In some embodiments, an underfill material 116 is applied to fill a space between the interposer 110 and the package substrate 100. The underfill material 116 may comprise an insulating material such as an epoxy, a resin, a filler material, a stress release agent (SRA), an adhesion promoter, another material, or a combination thereof. The underfill material 116 may surround the conductive connectors 112 to improve reliability of the conductive connectors 112.

The semiconductor chips 120 and 121 are bonded to the interposer 110 via multiple conductive connectors 122 by, for example, flip-chip bonding or surface mounting. One set of the conductive connectors 122 are formed on or under the semiconductor chip 120, and another set of the conductive connectors 122 are formed on or under the semiconductor chip 121. The conductive connectors 122 may be formed of metals such as copper, aluminum, gold, nickel, silver, platinum, tin, or a combination thereof. The conductive connectors 122 may have various configurations. For example, the conductive connectors 122 are solder balls, bumps, pads or pillars. In some embodiments, the conductive connectors 122 are microbumps. The conductive connectors 122 allow an electrical connection between each of the semiconductor chips 120 and 121 and the interposer 110. In some embodiments, the semiconductor chips 120 and 121 are electrically connected to each other via the redistribution lines and/or conductive vias 114 in the interposer 110. In some embodiments, the redistribution lines and/or conductive vias 114 are electrically connected to the conductive connectors 112 and 122.

The semiconductor chips 120 and 121 can be any suitable integrated circuit chips as required for a particular application. In some embodiments, the semiconductor chips 120 and 121 are graphics processing unit (GPU) chips, central processing unit (CPU) chips, microcontroller chips, flash chips, dynamic random-access memory (DRAM) chips, static random-access memory (SRAM) chips, other forms of integrated circuit memory, processing circuits, imaging components, active components, and/or passive components. The semiconductor chips 120 and 121 may be the same type or different types of chips. The semiconductor chips 120 and 121 are separated from each other and may have the same size or different sizes. In some embodiments, more than two semiconductor chips are bonded to the interposer 110.

In some embodiments, an underfill material 126 is applied to fill a space between the semiconductor chip 120 and the interposer 110 and a space between the semiconductor chip 121 and the interposer 110. The underfill material 126 may include a material same as or similar to that of the underfill material 116. The underfill material 126 may surround the conductive connectors 122 to improve reliability of the conductive connectors 122.

The MEMS structure 30 may be bonded to the semiconductor chips 120 and 121 by an adhesive 140, as shown in FIG. 1. In some embodiments, a width W1 of the MEMS structure 30 is less than a width W2 of the packaging structure 20. In some embodiments, a sidewall of the MEMS structure 30 and a sidewall of the semiconductor chip 120 or the semiconductor chip 121 are horizontally offset.

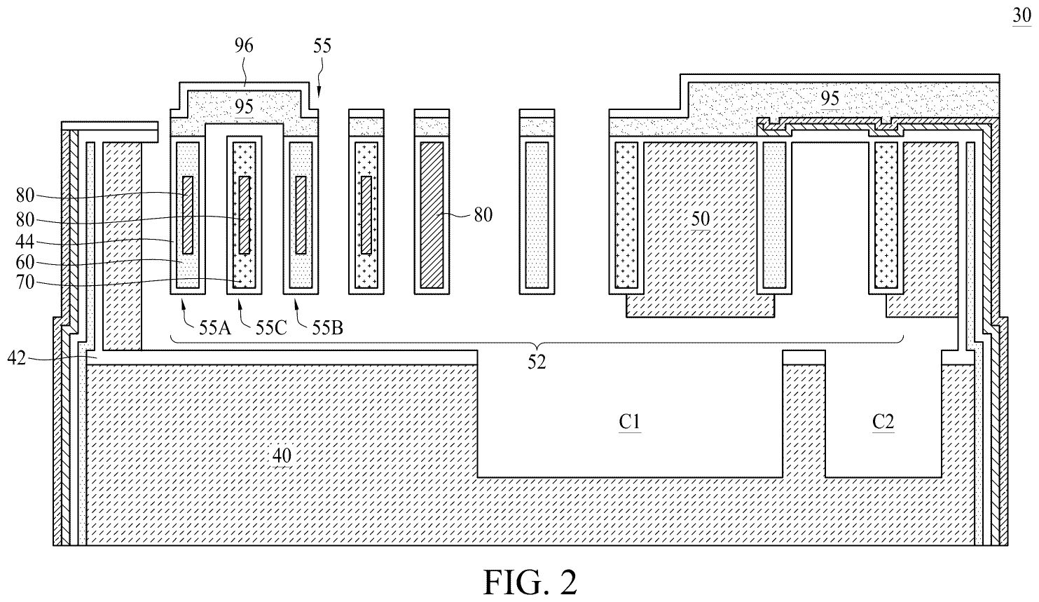

FIG. 2 is a schematic cross-sectional view of the MEMS structure 30 in FIG. 1 according to some embodiments of the present disclosure. In some embodiments, the MEMS structure 30 includes a lower substrate 40 bonded to an upper substrate 50 via a dielectric material 42. The lower substrate 40 and the upper substrate 50 are respectively patterned to desired patterns according to different applications of the MEMS structure 30. In some embodiments, the lower substrate 40 has one cavity C1 or multiple cavities C1 and C2. In some embodiments, the upper substrate 50 has multiple finger structures 52. Surfaces of the finger structures 52 may be covered by a dielectric material 44. Some of the finger structures 52 are fixed at one end and free at another end, and others of the finger structures 52 are fixed at both ends. The finger structures 52 are disposed over the cavities C1 and C2 formed in the lower substrate 40. The free ends of the finger structures 52 are cantilevered over the cavities C1 and C2. In some embodiments, some of the finger structures 52 having free ends (for example, leftmost three of the finger structures 52) function as a movable element 55.

In some embodiments, the movable element 55 includes a first movable member 55A, a second movable member 55B and a third movable member 55C. The first, second and third movable members 55A, 55B and 55C may be parallel to each other. In some embodiments, the first and second movable members 55A and 55B include a piezoelectric material 80 surrounded by a semiconductive material 60. In some embodiments, the semiconductive material is polycrystalline silicon or the like. In some embodiments, the third movable member 55C includes the piezoelectric material 80 surrounded by a metallic material 70. In some embodiments, the movable element 55 includes a lid or a cap 95 connecting the first movable member 55A to the second movable member 55B. The cap structure 95 is separated from the third movable member 55C. In some embodiments, the cap structure 95 is made of aluminum, copper or an alloy thereof. The movable element 55 illustrated in FIG. 2 may be referred to as a comb structure. That is, the movable element 55 including the movable members 55A to 55C and the cap structure 95 has a comb shape. In other embodiments, the movable element 55 can take a form of a single cantilevered beam extending over a cavity, a flexible membrane suspended over a substrate or a cavity in a substrate, or any other well-known alternative.

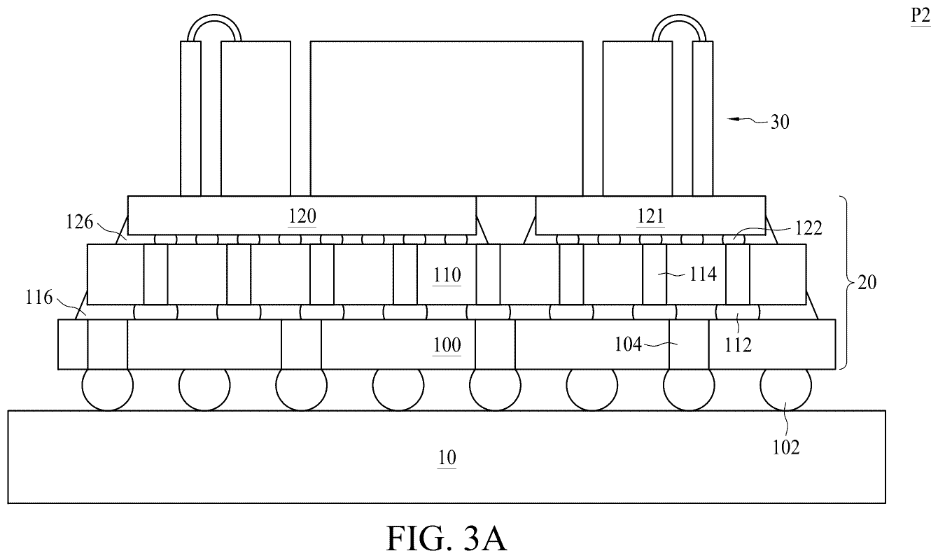

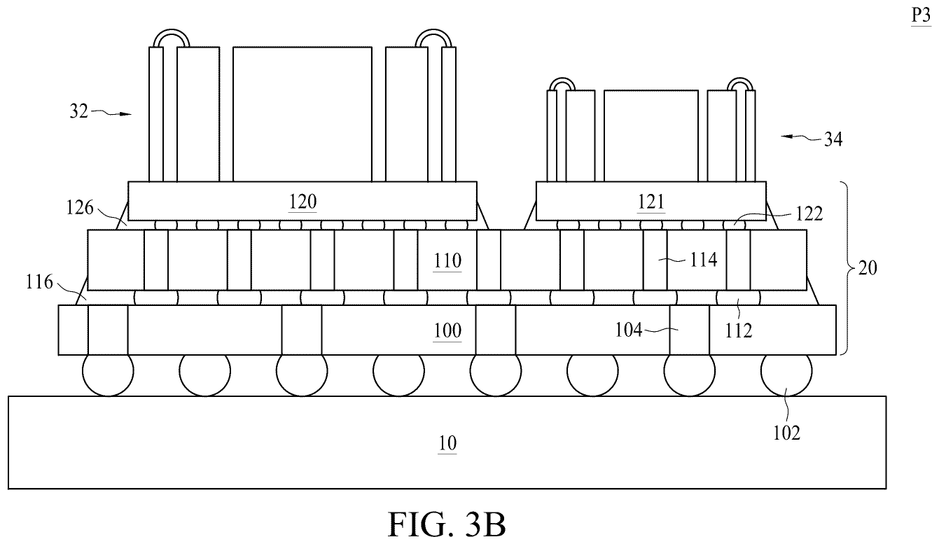

FIG. 3A is a schematic cross-sectional view of a semiconductor device P2 according to various embodiments of the present disclosure. The semiconductor device P2 is similar to the semiconductor device P1 in FIG. 1, except that in the semiconductor device P2, the MEMS structure 30 is bonded directly to the semiconductor chips 120 and 121. In some embodiments, at least a portion of the MEMS structure 30 is in contact with the semiconductor chip 120, and another portion of the MEMS structure 30 is in contact with the semiconductor chip 121. In some embodiments, a space is formed between the package structure 20, the MEMS structure 30, the semiconductor chip 120 and the semiconductor chip 121.

FIG. 3B is a schematic cross-sectional view of a semiconductor device P3 according to various embodiments of the present disclosure. The semiconductor device P3 is similar to the semiconductor device P2 in FIG. 3A, except that the semiconductor device P3 includes two MEMS structures 32 and 34 disposed over the packaging structure 20. The MEMS structures 32 and 34 may be the same as or similar to the MEMS structure 30 in FIG. 2. In some embodiments, the MEMS structure 32 is mounted on the semiconductor chip 120, and the MEMS structure 34 is mounted on the semiconductor chip 121.

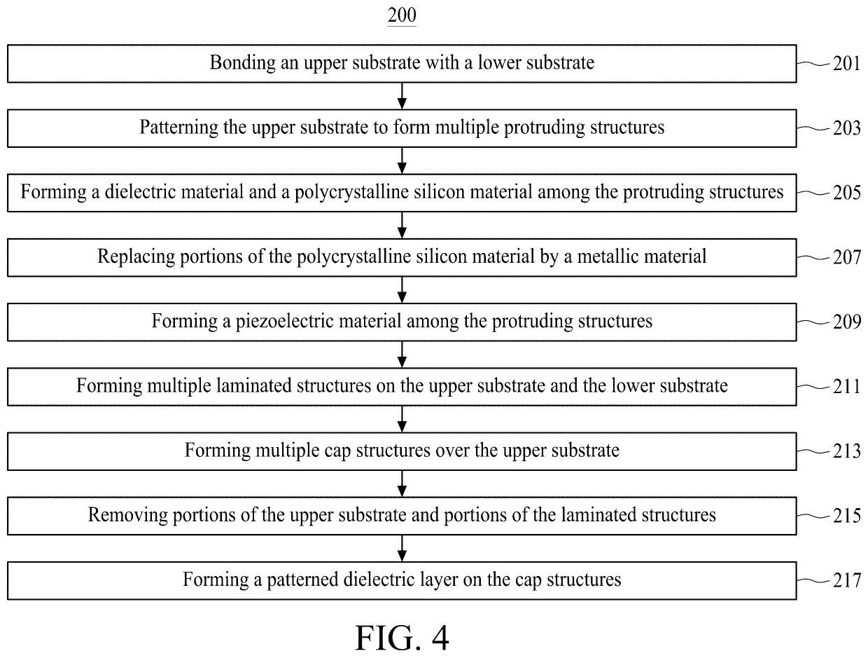

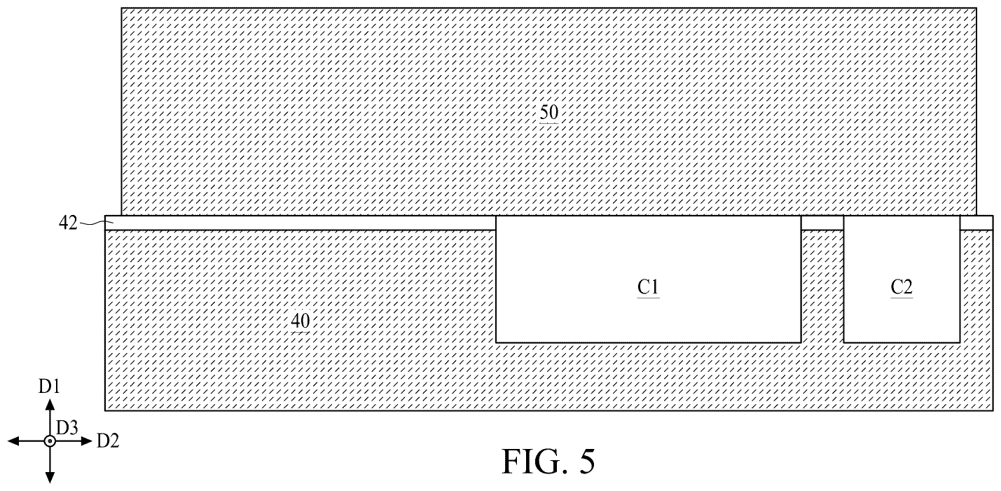

FIG. 4 is a flow diagram showing a method 200 for manufacturing the MEMS structure 30 in FIG. 2 according to some embodiments of the present disclosure. FIGS. 5 to 25 are schematic cross-sectional views illustrating sequential operations of the method 200 in FIG. 4. The method 200 is merely an example, and is not intended to limit the scope of the present disclosure. Additional operations can be provided before, during, and after the method 200, and some operations described can be replaced, eliminated, or moved around for additional embodiments of the method 200.

In operation 201 of the method 200, an upper substrate 50 is bonded to a lower substrate 40, as shown in FIG. 5. In some embodiments, the upper substrate 50 and the lower substrate 40 are formed of silicon, or other materials such as silicon germanium, silicon carbide, or the like. Alternatively, the upper substrate 50 and the lower substrate 40 may be silicon-on-insulator (SOI) substrates. The SOI substrate includes a layer of semiconductor material (e.g., silicon, germanium, or the like) formed over an insulator layer (e.g., buried oxide), which is formed in a silicon substrate. In some embodiments, the upper substrate 50 is bonded to the lower substrate 40 via a dielectric material 42. The dielectric material 42 may be a low-k dielectric material, such as silicon dioxide (SiO₂). In some embodiments, the lower substrate 40 has multiple cavities C1 and C2.

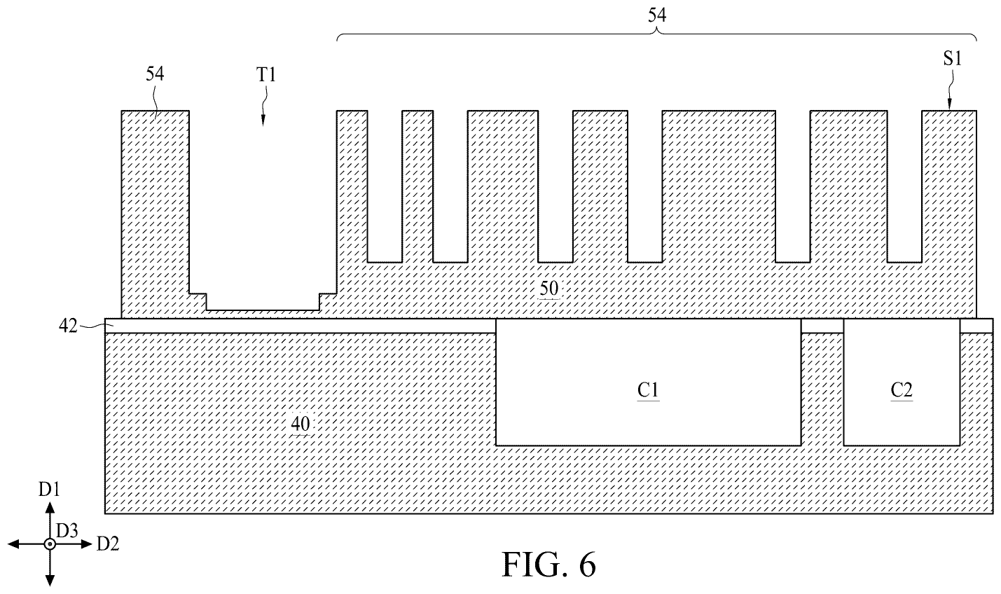

In operation 203 of the method 200, the upper substrate 50 is patterned to form multiple protruding structures 54 and 56, as shown in FIGS. 6 to 8. Referring to FIG. 6, a first etching operation is formed on a top surface S1 of the upper substrate 50 via a first photoresist pattern (not shown). The first etching operation removes portions of the upper substrate 50, thus forming the protruding structures 54. The protruding structures 54 face a first direction D1 that is a thickness direction of the upper substrate 50. The protruding structures 54 may be arranged along a second direction D2 perpendicular to the first direction D1. The protruding structures 54 may extend along a third direction D3 perpendicular to the first direction D1 and the second direction D2. In some embodiments, a trench T1 is formed between two of the protruding structures 54. In some embodiments, the trench T1 is not aligned with the cavity C1 or the cavity C2 along the first direction D1.

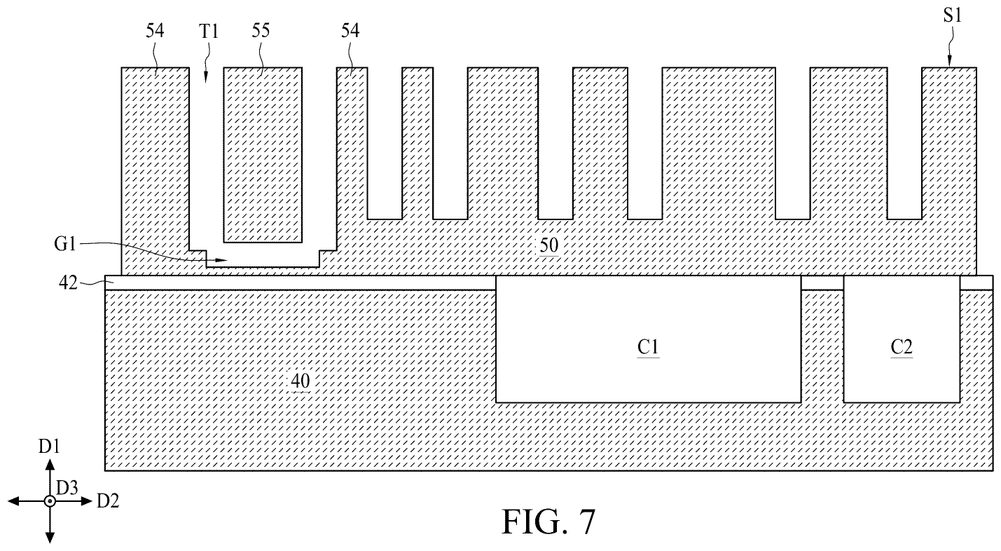

Referring to FIG. 7, a filling member 55 is deposited or inserted into the trench T1. The filling member 55 is made of a material same as or similar to that of the upper substrate 50. The trench T1 may be incompletely filled by the filling member 55. That is, a gap G1 is formed between the filling member 55 and the upper substrate 50.

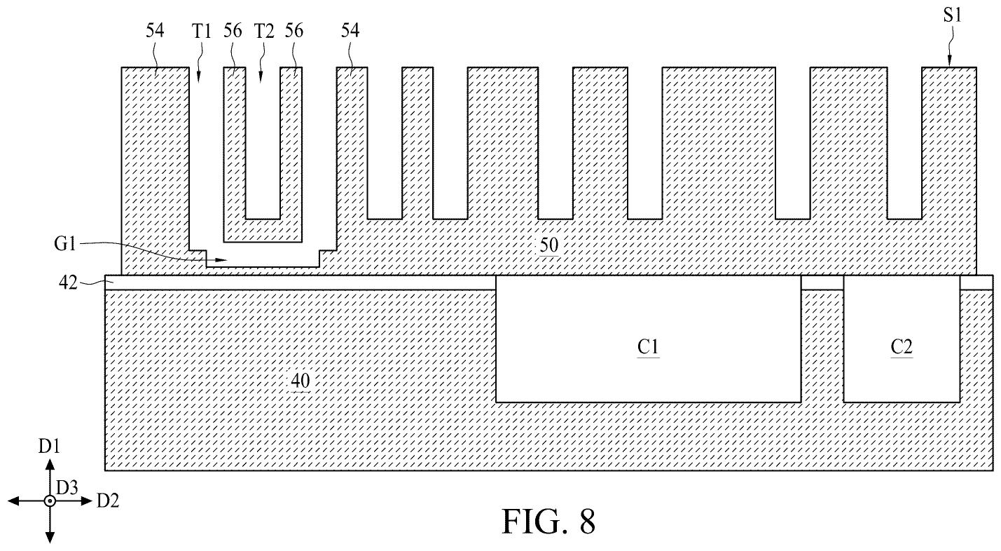

Referring to FIG. 8, a second etching operation is formed on the filling member 55 via a second photoresist pattern (not shown). The second etching operation removes a portion of the filling member 55, thus forming the protruding structures 56 separated by a trench T2. The trench T2 is formed in the filling member 55 and does not penetrate the filling member 55. The protruding structures 56 face the first direction D1 and are parallel to the protruding structures 54.

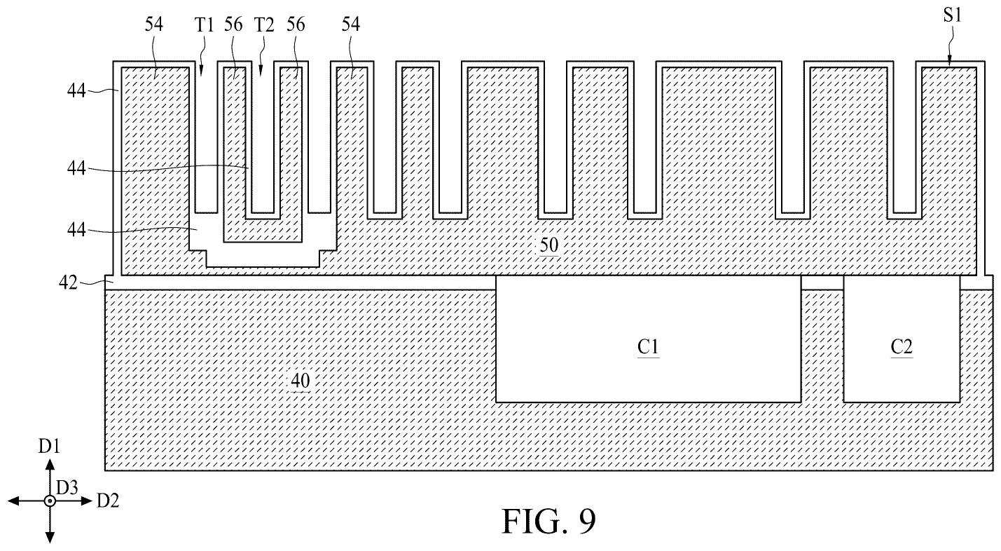

In operation 205 of the method 200, a dielectric material 44 and a semiconductive material 60 are formed among the protruding structures 54 and 56, as shown in FIGS. 9 to 11. Referring to FIG. 9, the dielectric material 44 is conformally formed on the upper substrate 50. The dielectric material 44 may be formed by chemical vapor deposition (CVD) or thermal growth. The dielectric material 44 may be a low-k dielectric material, such as silicon dioxide. In some embodiments, the gap G1 between the filling member 55 and the upper substrate 50 is filled by the dielectric material 44.

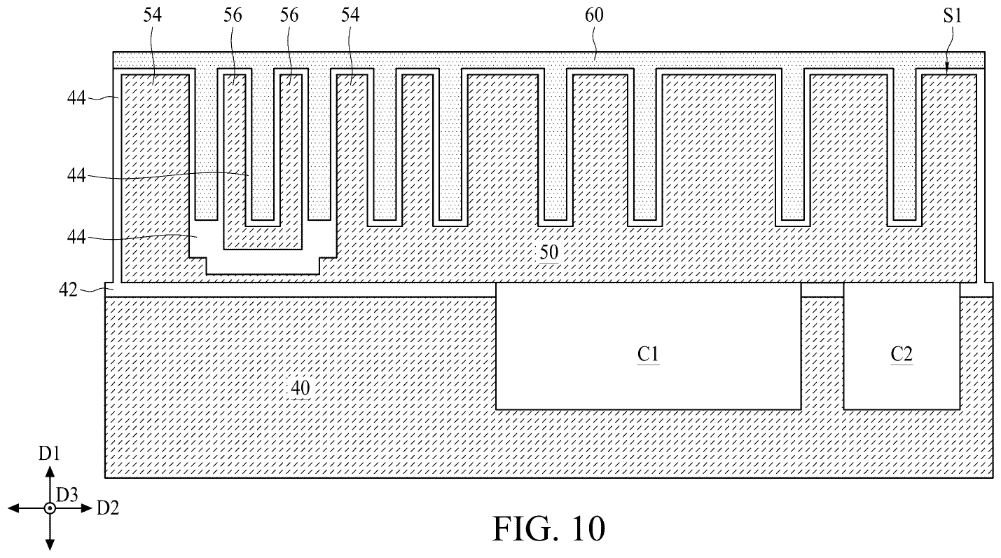

Referring to FIG. 10, the semiconductive material 60 is deposited on the upper substrate 50. The semiconductive material 60 covers the dielectric material 44 and the protruding structures 54 and 56.

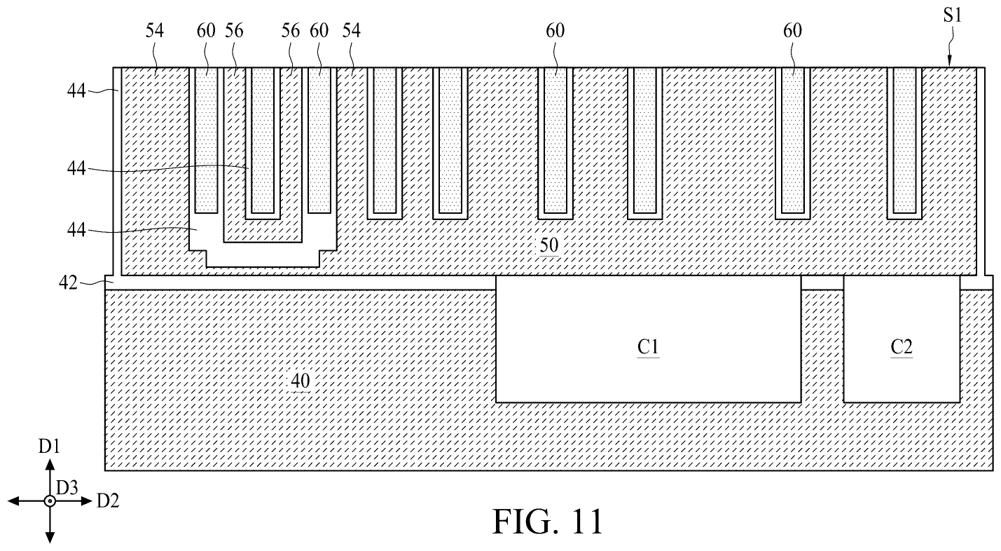

Referring to FIG. 11, portions of the semiconductive material 60 and the dielectric material 44 over the top surface S1 of the upper substrate 50 are removed. Therefore, the top surface S1 of the upper substrate 50, that is, top surfaces of the protruding structures 54 and 56, are re-exposed. The semiconductive material 60 is surrounded by the dielectric material 44. The dielectric material 44 and the semiconductive material 60 are disposed among the protruding structures 54 and 56.

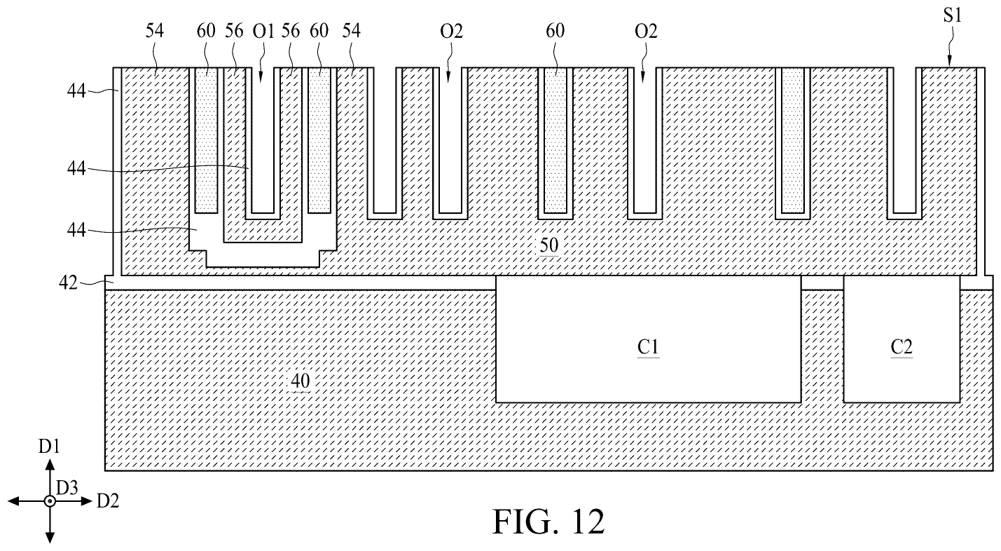

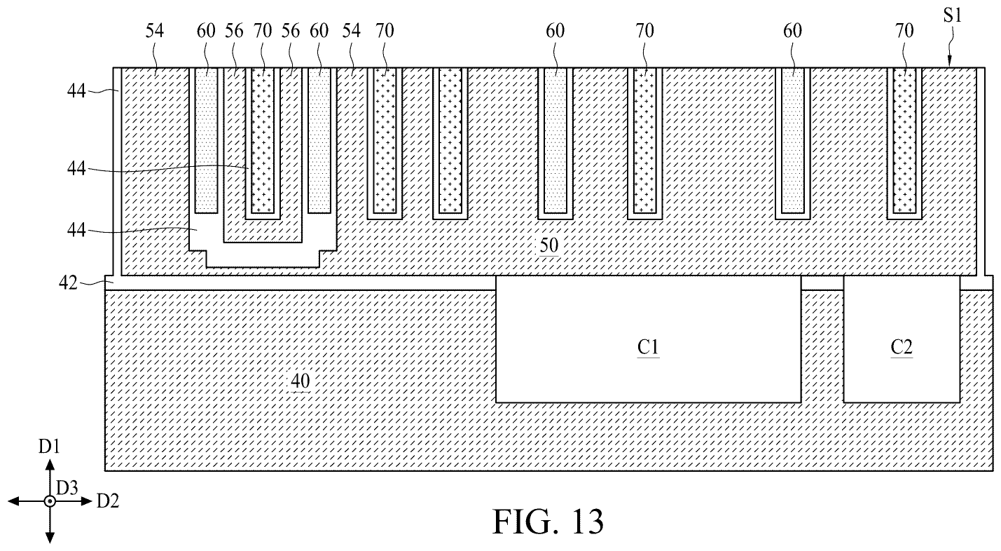

In operation 207 of the method 200, portions of the semiconductive material 60 are replaced by a metallic material 70, as shown in FIGS. 12 and 13. Referring to FIG. 12, the semiconductive material 60 between the protruding structures 56 and some of adjacent protruding structures 54 is removed. A first opening O1 is formed between the protruding structures 56 and a second opening O2 is formed between the adjacent protruding structures 54.

Referring to FIG. 13, the metallic material 70 is deposited on the upper substrate 50. The metallic material 70 fills the first opening O1 and the second openings O2. The metallic material 70 may include copper, aluminum, gold, nickel, silver, platinum, tin, or a combination thereof. Excess metallic material 70 over the top surface S1 of the upper substrate 50 is removed, thus re-exposing the top surfaces of the protruding structures 54 and 56.

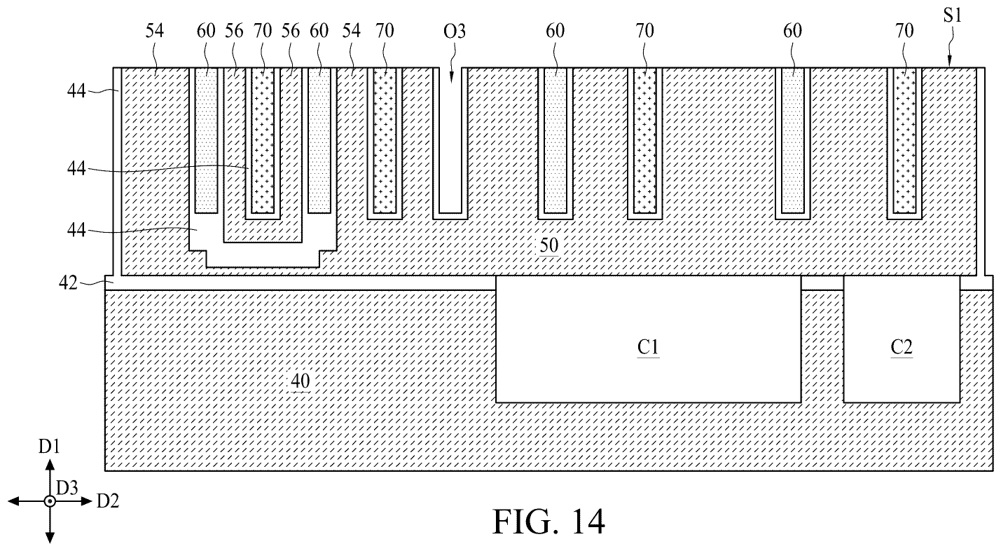

In operation 209 of the method 200, a piezoelectric material 80 is formed among the protruding structures 54 and 56, as shown in FIGS. 14 to 18. Referring to FIG. 14, another etching operation is used to remove the metallic material 70 between one pair of the adjacent protruding structures 54, thus forming a third opening O3.

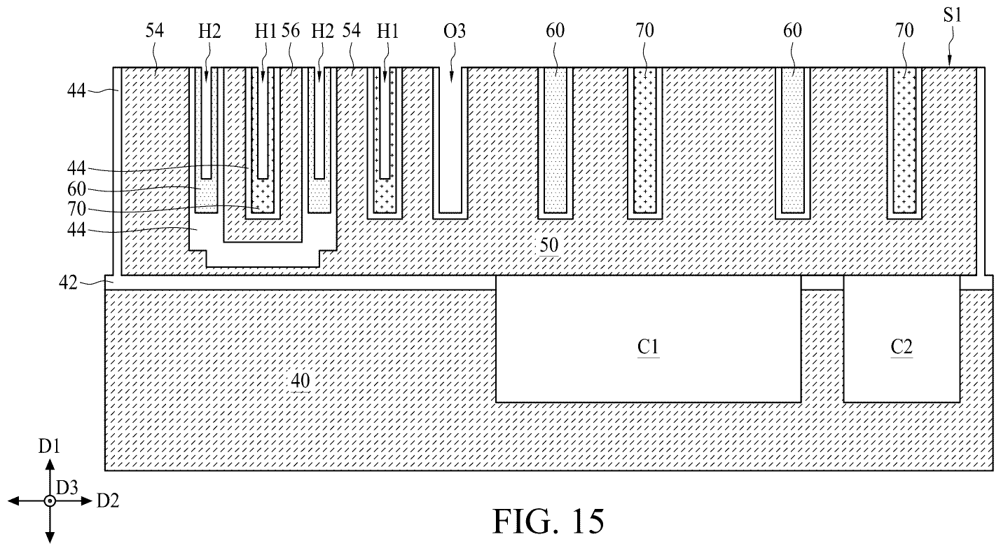

Referring to FIG. 15, sequential etch-back operations are used to remove portions of the metallic material 70 to form multiple first holes H1 and to remove portions of the semiconductive material 60 to form multiple second holes H2. The first hole H1 is formed in the metallic material 70, and the second hole H2 is formed in the semiconductive material 60. A sequence of forming the first hole H1, the second hole H2 and the third opening O3 is not limited and can be adjusted according to the use of different photomasks in the etch-back operations.

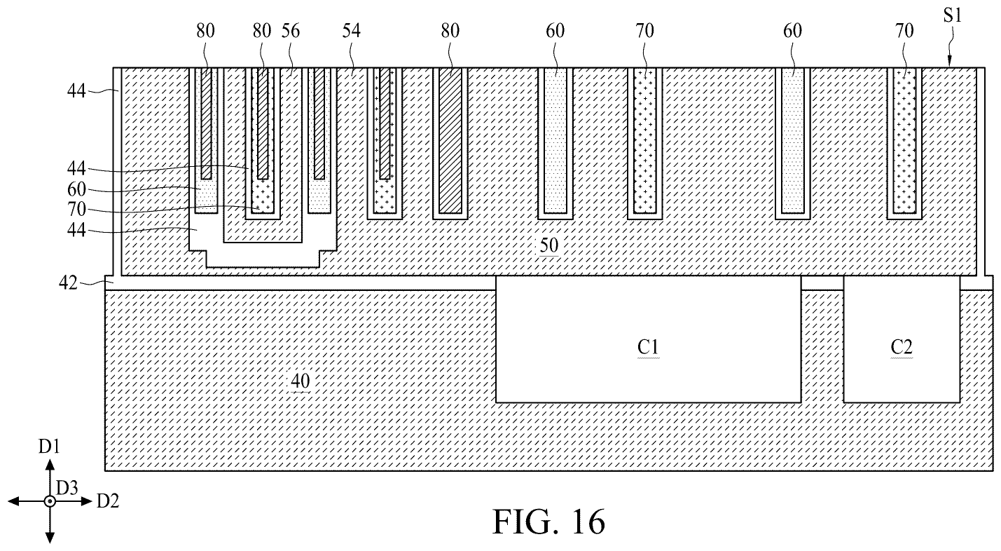

Referring to FIG. 16, the piezoelectric material 80 is deposited on the upper substrate 50. The piezoelectric material 80 fills the first hole H1, the second hole H2 and the third opening O3. In some embodiments, the piezoelectric material 80 has a formula of ABO₃, where a principal component of A is barium (Ba) or lead (Pb), and a principal component of B includes an element among niobium (Nb), magnesium (Mg), zinc (Zn), scandium (Sc), nickel (Ni), manganese (Mn), cobalt (Co), ytterbium (Yb), indium (In), iron (Fe), titanium (Ti) and other metals. Excess piezoelectric material 80 over the top surface S1 of the upper substrate 50 is removed, thus re-exposing the top surfaces of the protruding structures 54 and 56. Some of the piezoelectric material 80 is surrounded by the semiconductive material 60, and other of the piezoelectric material 80 is surrounded by the metallic material 70.

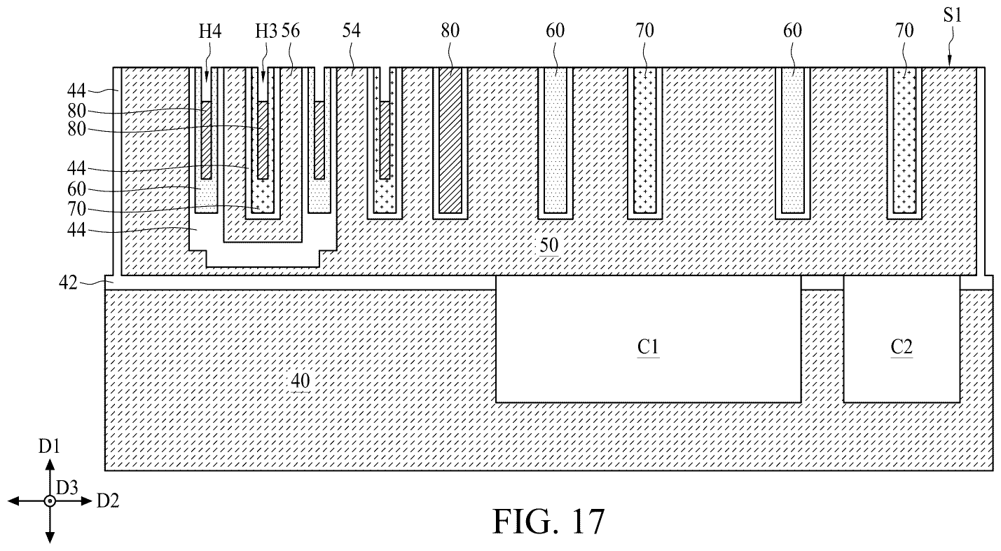

Referring to FIG. 17, sequential etch-back operations are used to remove portions of the piezoelectric material 80 to form multiple third holes H3 and fourth holes H4. The third hole H3 is defined by the metallic material 70 and the piezoelectric material 80. The fourth hole H4 is defined by the semiconductive material 60 and the piezoelectric material 80. A sequence of forming the third hole H3 and the fourth hole O4 is not limited and can be adjusted according to the use of different photomasks in the etch-back operations.

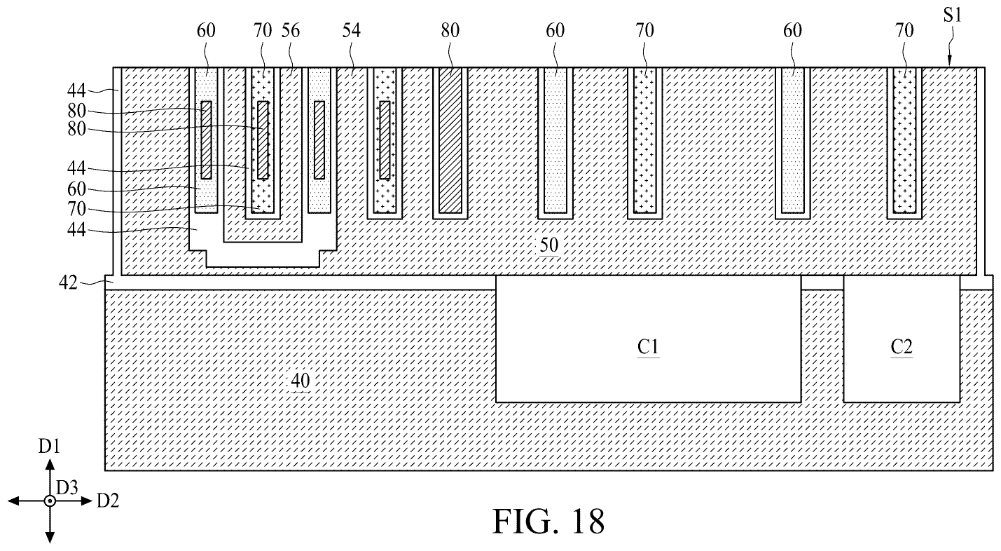

Referring to FIG. 18, additional metallic material 70 is used to fill the third holes H3. Excess metallic material 70 over the top surface S1 of the upper substrate 50 is removed, thus re-exposing the top surfaces of the protruding structures 54 and 56. Subsequently, additional semiconductive material 60 is used to fill the fourth holes H4. Excess semiconductive material 60 over the top surface S1 of the upper substrate 50 is removed, thus re-exposing the top surfaces of the protruding structures 54 and 56. A sequence of filling the third holes H3 and the fourth holes H4 is not limited and can be adjusted according to practical requirements. As a result, the piezoelectric material 80 is disposed among the protruding structures 54 and 56. Some of the piezoelectric material 80 is embedded in the semiconductive material 60, and some of the piezoelectric material 80 is embedded in the metallic material 70.

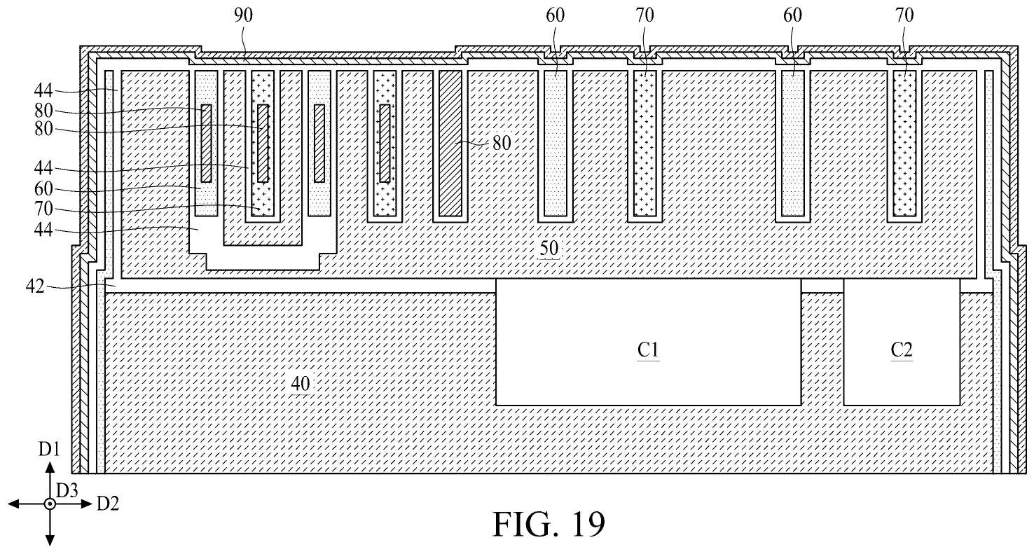

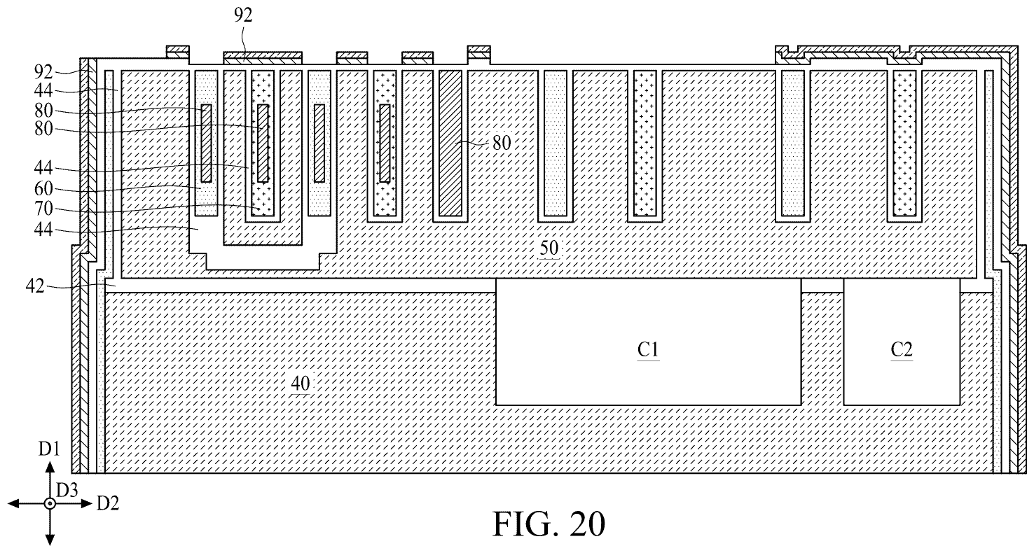

In operation 211 of the method 200, multiple laminated structures 92 are formed on the upper substrate 50 and the lower substrate 40, as shown in FIGS. 19 and 20. Referring to FIG. 19, multiple dielectric layers 90 are sequentially and conformally deposited on the upper substrate 50 and the lower substrate 40. The dielectric layers 90 may include silicon dioxide, silicon nitride, silicon glass, high k dielectrics, or the like. In some embodiments, the dielectric layers 90 are used to protect the upper substrate 50 and the lower substrate 40 from being contaminated from moisture or dust.

Referring to FIG. 20, the dielectric layers 90 are patterned. One or more etching operations may be used to remove portions of the dielectric layers 90, thereby forming the laminated structures 92.

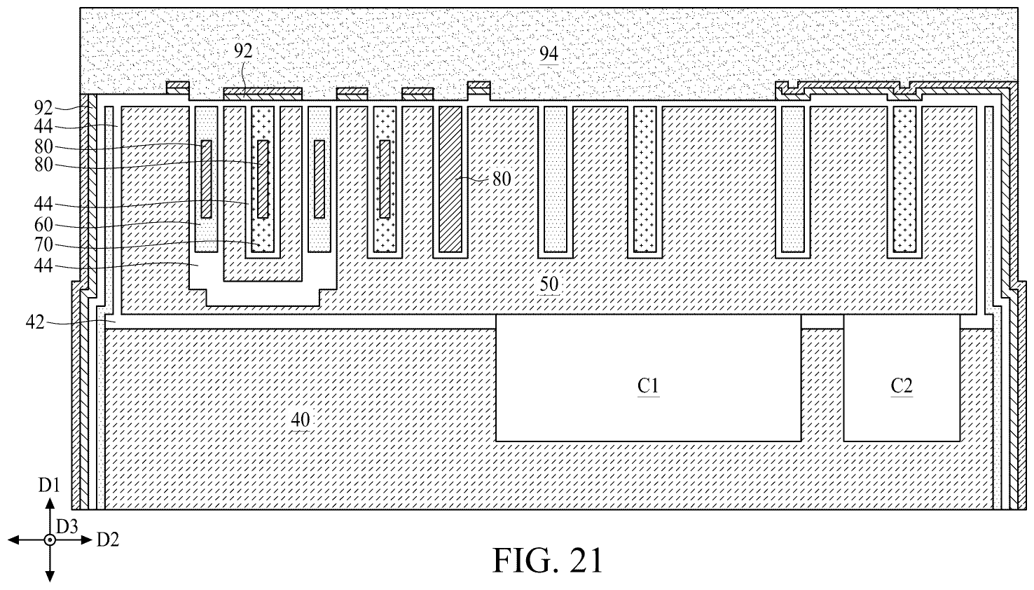

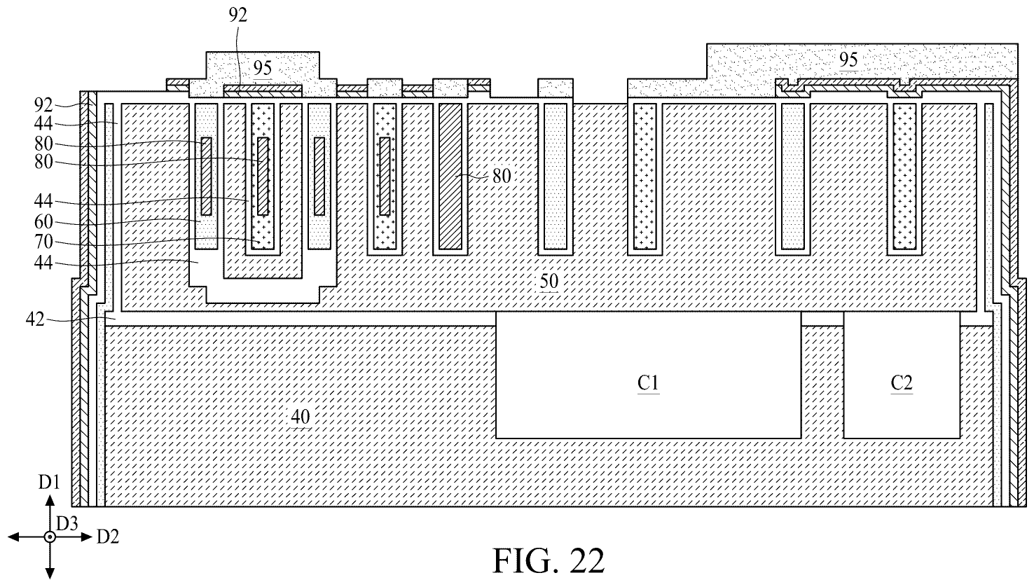

In operation 213 of the method 200, multiple cap structures 95 are formed over the upper substrate 50, as shown in FIGS. 21 and 22. Referring to FIG. 21, a conductive material 94 is deposited over the upper substrate 50 using, for example, physical vapor deposition (PVD) or electroplating. In some embodiments, the conductive material 94 includes copper, aluminum, or a combination thereof.

Referring to FIG. 22, the conductive material 94 is patterned. One or more etching operations may be used to remove portions of the conductive material 94, thereby forming the cap structures 95.

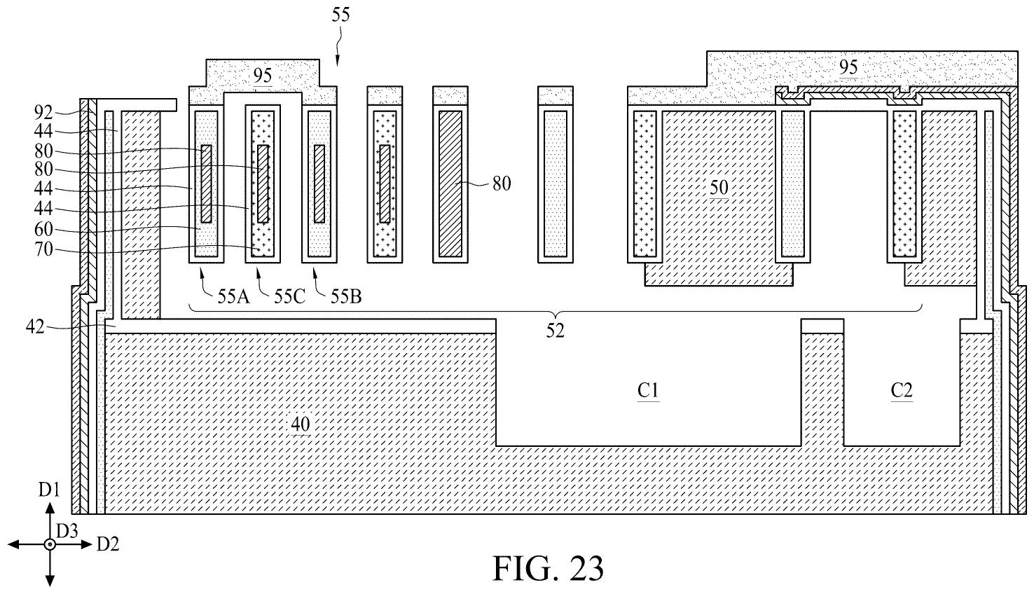

In operation 215 of the method 200, portions of the upper substrate 50 and portions of the laminated structures 92 are removed, as shown in FIG. 23. In some embodiments, a chemical including carbon fluoride (CF₄) and/or hydrofluoric acid (HF) is used to react portions of the upper substrate 50. The chemical may react with the laminated structure 92. With a careful control, portions of the reacted upper substrate 50 and the reacted laminated structures 92 are removed.

In some embodiments, the remaining upper substrate 50 includes multiple finger structures 52. Some of the finger structures 52 are fixed at one end and free at another end, and others of the finger structures 52 are fixed at both ends. The finger structures 52 are disposed over the cavities C1 and C2 formed in the lower substrate 40. The free ends of the finger structures 52 are cantilevered over the cavities C1 and C2. In some embodiments, surfaces of the finger structures 52 may be covered by the dielectric material 44. In some embodiments, some of the finger structures 52 having free ends (for example, leftmost three of the finger structures 52) function as a movable element 55.

In some embodiments, the movable element 55 includes a first movable member 55A, a second movable member 55B and a third movable member 55C. The first, second and third movable members 55A, 55B and 55C are parallel to each other. The third movable member 55C is between the first movable member 55A and the second movable member 55B. In some embodiments, the first and second movable members 55A and 55B include the piezoelectric material 80 surrounded by the semiconductive material 60. In some embodiments, the third movable member 55C includes the piezoelectric material 80 surrounded by the metallic material 70.

In some embodiments, the cap structure 95 connects the first movable member 55A to the second movable member 55B. The cap structure 95 is separated from the third movable member 55C. The movable element 55 illustrated in FIG. 23 may be referred to as a comb structure. That is, the movable element 55 including the movable members 55A to 55C and the cap structure 95 has a comb shape. In other embodiments, the movable element 55 can take a form of a single cantilevered beam extending over a cavity, a flexible membrane suspended over a substrate or a cavity in a substrate, or any other well-known alternative.

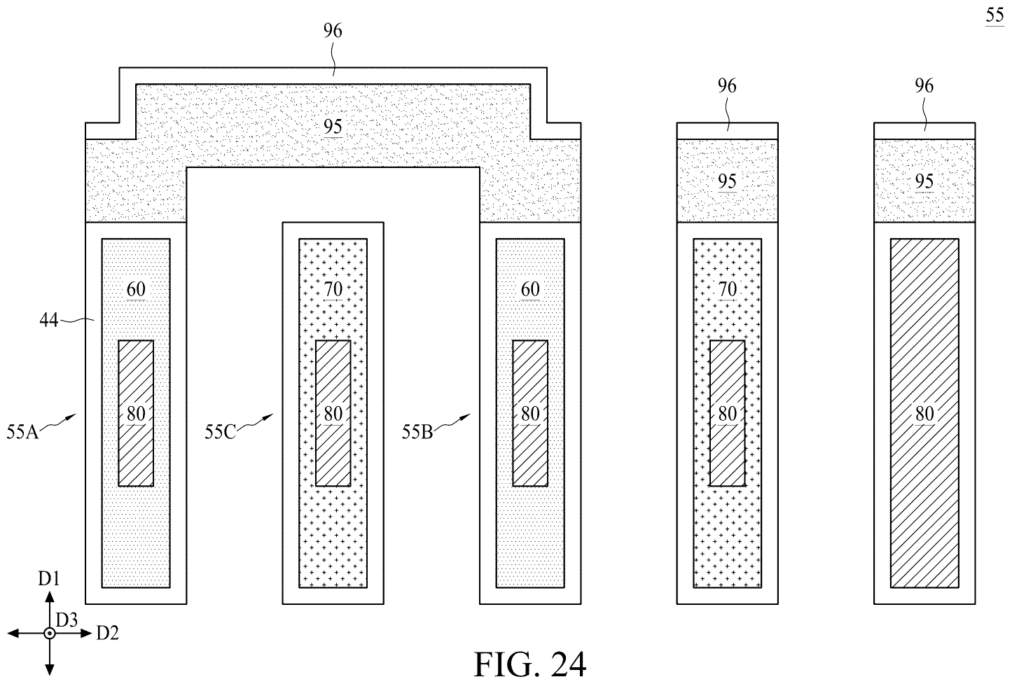

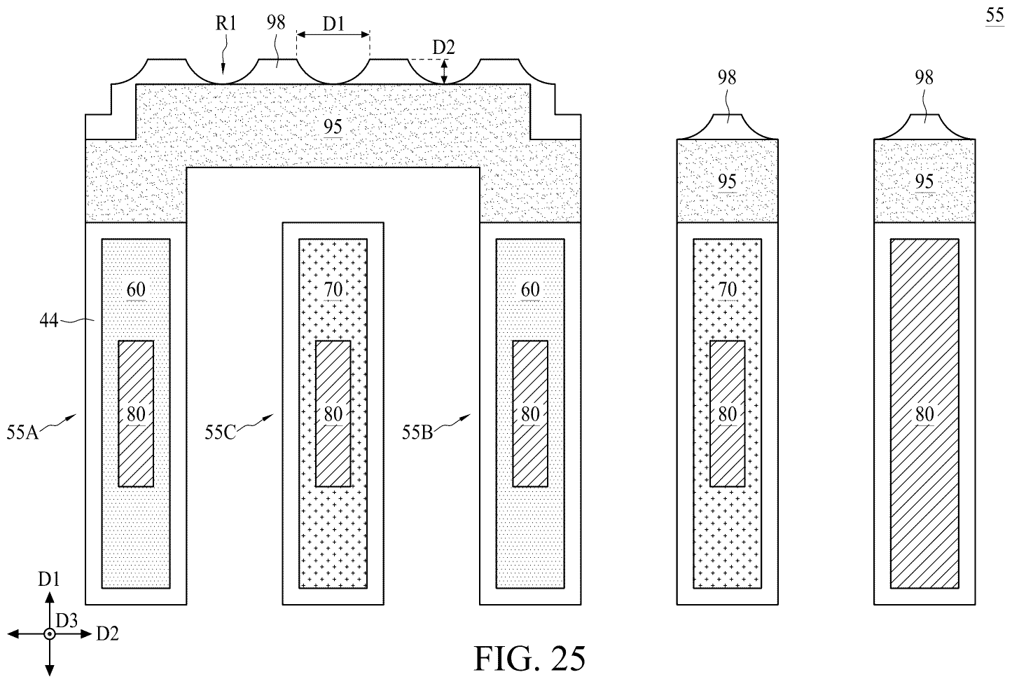

In operation 217 of the method 200, a patterned dielectric layer 98 is formed on the cap structures 95, as shown in FIGS. 24 and 25. Referring to FIG. 24, FIG. 24 is an enlarged view of the movable element 55 in FIG. 23. In some embodiments, a dielectric layer 96 is formed on the cap structures 95. The dielectric layer 96 may be made of silicon dioxide, silicon nitride, silicon glass, high k dielectrics, or the like. Referring to FIG. 25, an etching operation is used to remove portions of the dielectric layer 96, thus forming the patterned dielectric layer 98. The patterned dielectric layer 98 has an increased surface roughness compared to the dielectric layer 96. The patterned dielectric layer 98 has multiple protrusions arranged alternately with recesses R1. The protrusions face away from the first, second and third movable members 55A, 55B and 55C. In some embodiments, the recess R1 has a diameter D1 between about 1 nanometer (nm) and about 20 nm. In some embodiments, the recess R1 has a depth D2 between about 1 nm and about 20 nm. At this stage, the formation of the MEMS structure 30 is complete.

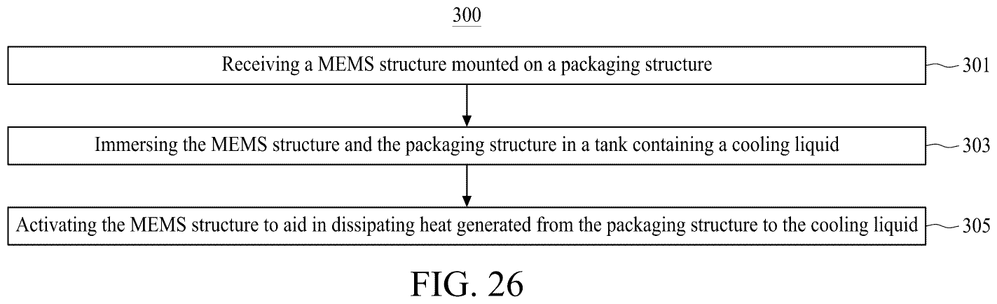

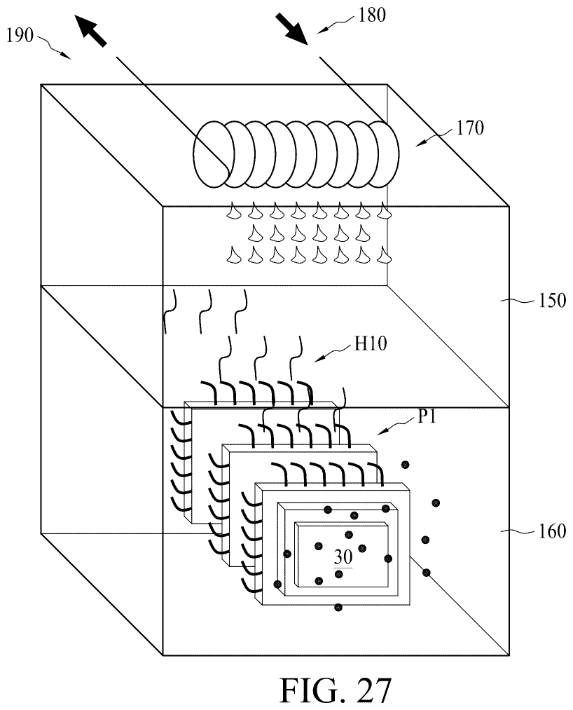

FIG. 26 is a flow diagram showing a method 300 for operating the semiconductor device P1 in FIG. 1 according to some embodiments of the present disclosure. FIG. 27 is a schematic perspective view illustrating an operation of the method 300 in FIG. 26. The method 300 can also be used for operating the semiconductor device P2 in FIG. 3A or the semiconductor device P3 in FIG. 3B. The method 300 is merely an example, and is not intended to limit the scope of the present disclosure. Additional operations can be provided before, during, and after the method 300, and some operations described can be replaced, eliminated, or moved around for additional embodiments of the method 300.

In operation 301 of the method 300, the MEMS structure 30 mounted on the packaging structure 20 is received. The packaging structure 20 may be mounted on a PCB, or may be not mounted on a PCB.

In operation 303 of the method 300, the MEMS structure 30 and the packaging structure 20 are immersed in a tank 150 containing a cooling liquid 160. In some embodiments, the cooling liquid 160 does not react with any part of the MEMS structure 30 or with any part of the packaging structure 20. The packaging structure 20 can be in operation before, during or after being immersed in the cooling liquid 160. In some embodiments, the cooling liquid 160 is used to dissipate heat H10 generated from the packaging structure 20. During the operation of the packaging structure 20, the heat H10 may be continuously generated from, for example, the semiconductor chips 120 and 121. The cooling liquid 160 can be used to cool the semiconductor chips 120 and 121 of the packaging structure 20. The heat H10 can be dissipated from the packaging structure 20 to the cooling liquid 160.

In operation 305 of the method 300, the MEMS structure 30 is activated to aid in dissipating the heat H10 generated from the packaging structure 20 to the cooling liquid 160. In some embodiments, when the piezoelectric material 80 in the movable element 55 sustains a physical force, which might be, for example, movement or pressure caused by temperature change, the piezoelectric material 80 generates an output signal from the applied physical force, requiring no external voltage. Such process may be referred to as a piezoelectric effect that enables the output signal. The output signal may trigger or enhance a motion of the movable element 55. In some embodiments, the movable element 55 is actuated to move or vibrate relative to the packaging structure 20. In some embodiments, the actuation of the movable element 55 and the operation of the packaging structure 20 are performed simultaneously. That is, the packaging structure 20 (or the semiconductor chips 120 and 121) are under operation when the movable element 55 is in motion or vibration. Referring to FIGS. 1 and 25, in some embodiments, the movable element 55 is movable along the first direction D1, the second direction D2 or the third direction D3. In some embodiments, the first, second and third movable members 55A, 55B and 55C are bendable. In some embodiments, the actuation of the movable element 55 enhances a convection of the cooling liquid 160. The convection can accelerate the dissipation of the heat H10 from the packaging structure 20 to the cooling liquid 160. In some embodiments, the cooling liquid 160 has more contact area with the movable element 55 because of the surface roughness of the patterned dielectric layer 98. In such embodiments, the movable element 55 can cause more convection of the cooling liquid 160. Furthermore, the vibration of the first, second and third movable members 55A, 55B and 55C may generate many bubbles in the cooling liquid 160. In some embodiments, the patterned dielectric layer 98 of the movable element 55 generates more bubbles compared with the unpatterned dielectric layer 96. The bubbles can aid in dissipating the heat H10 from the packaging structure 20 to the cooling liquid 160.

In some embodiments, the tank 150 includes a condenser 170 disposed over the cooling liquid 160. The condenser 170 has an inlet 180 for receiving cold water and an outlet 190 for pumping out hot wafer. Since the cooling liquid 160 constantly absorbs the heat H10, some of the cooling liquid 160 may be vaporized. The condenser 170 may be used to condense a vapor or steam of the cooling liquid 160. Therefore, the condensed vapor will fall back into the cooling liquid 160.

In some embodiments, the MEMS structure 30 includes a detector such as a temperature detector. The temperature detector can be used to detect a temperature of the packaging structure 20 (or the semiconductor chips 120 and 121) when the packaging structure 20 is in operation and transmit a signal associated with the temperature to the MEMS structure 30. In some embodiments, when the temperature of the packaging structure 20 is substantially greater than a predetermined temperature, the actuation of the movable element 55 is triggered or accelerated to enhance heat dissipation from the packaging structure 20.

One aspect of the present disclosure provides a semiconductor device. The semiconductor device includes: a circuit board; a packaging structure disposed over and bonded to the circuit board; and a MEMS structure disposed over and bonded to the packaging structure and including a movable element. The movable element is movable relative to the packaging structure and the circuit board upon an operation of the packaging structure.

One aspect of the present disclosure provides another semiconductor device. The semiconductor device includes: a chip; and an actuating structure, mounted over the chip. The actuating structure includes: a cavity; and a movable element, disposed over the cavity. The movable element includes a first movable member and a second movable member. The first movable member includes a first piezoelectric material surrounded by a first material, and the second movable member includes a second piezoelectric material surrounded by a second material different from the first material.

Another aspect of the present disclosure provides a method for operating a semiconductor device. The method includes: receiving a MEMS structure mounted on a packaging structure, wherein the MEMS structure includes a movable element disposed over a cavity; immersing the MEMS structure and the packaging structure in a tank containing a cooling liquid; operating the packaging structure after immersing the MEMS structure and the packaging structure; and actuating the movable element to move relative to the packaging structure. The actuation of the movable element enhances dissipation of the heat generated from the packaging structure during the operation to the cooling liquid.

The foregoing outlines features of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods or steps, presently existing or later to be developed, that perform substantially the same function or achieve substantially the same result as the corresponding embodiments described herein, can be utilized according to the present invention. Accordingly, the appended claims are intended to include within their scope such processes, machines, manufacture, compositions of matter, means, methods and steps.

What is claimed is:

1. A semiconductor device, comprising:
a circuit board;
a packaging structure disposed over and bonded to the circuit board; and
a microelectromechanical system (MEMS) structure disposed over and bonded to the packaging structure and including a movable element,
wherein the movable element is movable relative to the packaging structure and the circuit board upon an operation of the packaging structure.

2. The semiconductor device of claim 1, wherein the movable element has a comb shape.

3. The semiconductor device of claim 1, wherein the movable element includes piezoelectric material and metallic material.

4. The semiconductor device of claim 1, wherein the packaging structure includes:
a substrate;
an interposer, disposed over and bonded to the substrate; and
a first chip, disposed over and bonded to the interposer, wherein the MEMS structure is bonded to the first chip.

5. The semiconductor device of claim 4, wherein at least a portion of the MEMS structure is in contact with the first chip.

6. The semiconductor device of claim 4, wherein the MEMS structure is bonded to the first chip by an adhesive.

7. The semiconductor device of claim 4, wherein the packaging structure includes a second chip disposed over and bonded to the interposer and separated from the first chip, and the MEMS structure is bonded to the second chip.

8. The semiconductor device of claim 7, wherein the first chip and the second chip are respectively a graphics processing unit (GPU) chip, a central processing unit (CPU) chip, a memory chip or a flash chip.

9. The semiconductor device of claim 6, wherein a width of the MEMS structure is less than a width of the packaging structure.

10. A semiconductor device, comprising:
a chip; and
an actuating structure, mounted over the chip, wherein the actuating structure includes:
a cavity; and
a movable element, disposed over the cavity, wherein
the movable element includes a first movable member and a second movable member,
the first movable member includes a first piezoelectric material surrounded by a first material, and
the second movable member includes a second piezoelectric material surrounded by a second material different from the first material.

11. The semiconductor device of claim 10, wherein the first material is polycrystalline silicon, and the second material is metal.

12. The semiconductor device of claim 10, wherein
the actuating structure includes a cap structure connected to the first movable member, and
the cap structure includes a surface having a plurality of protrusions or a plurality of recesses and facing away from the first movable member and the second movable member.

13. The semiconductor device of claim 12, wherein the cap structure includes aluminum, copper or an alloy thereof.

14. A method of operating a semiconductor device, comprising:
receiving a MEMS structure mounted on a packaging structure, wherein the MEMS structure includes a movable element disposed over a cavity;
immersing the MEMS structure and the packaging structure in a tank containing a cooling liquid;
operating the packaging structure after immersing the MEMS structure and the packaging structure; and
actuating the movable element to move relative to the packaging structure,
wherein the actuation of the movable element enhances dissipation of heat generated from the packaging structure during the operation to the cooling liquid.

15. The method of claim 14, wherein the tank includes a condenser disposed over the cooling liquid, and the condenser is configured to condense a vapor of the cooling liquid.

16. The method of claim 14, further comprising detecting a temperature of the packaging structure by a detector, wherein the detector is configured to transmit a signal associated with the temperature of the packaging structure to the MEMS structure.

17. The method of claim 16, wherein the actuating of the movable element is performed when the temperature of the packaging structure is substantially greater than a predetermined temperature.

18. The method of claim 14, wherein the actuation of the movable element and the operation of the packaging structure are performed simultaneously.

19. The method of claim 14, wherein the movable element is movable along a first direction parallel to a thickness direction of the MEMS structure, and the movable element is movable along a second direction perpendicular to the first direction.

20. The method of claim 14, wherein the heat is dissipated by a convection of the cooling liquid.
